(19) United States
(12) Patent Application Publication
(10) Pub. No.: US 2025/0323051 A1
(43) Pub. Date: Oct. 16, 2025

(54) METHOD FOR MANUFACTURING SEMICONDUCTOR DEVICE AND SUBSTRATE PROCESSING SYSTEM

(71) Applicant: Tokyo Electron Limited, Tokyo (JP)

(72) Inventors: Tetsu OHTOU, Tokyo (JP); Koji WATANABE, Tokyo (JP); Tomonari YAMAMOTO, Tokyo (JP)

(21) Appl. No.: 19/251,537

(22) Filed: Jun. 26, 2025

Related U.S. Application Data
(63) Continuation of application No. PCT/JP2023/045598, filed on Dec. 20, 2023.

(30) Foreign Application Priority Data
Dec. 27, 2022 (JP) 2022-210178

(51) Int. Cl. H01L 21/308; H01L 21/027; H01L 21/311; H01L 21/66; H01L 21/67

(52) U.S. Cl. CPC H01L 21/3086; H01L 21/0274; H01L 21/3081; H01L 21/31144; H01L 21/67225; H01L 22/12

(57) ABSTRACT

A method for manufacturing a semiconductor device includes providing a substrate including a first film stack, a dielectric film, and a first mask film, the first film stack being disposed in a first region on the substrate, the dielectric film being disposed on the substrate to cover the first film stack, and the first mask film being disposed on the dielectric film, forming a plurality of openings in the first mask film, at least one of the plurality of openings being formed at a position overlapping a part of the first film stack in a plan view of the substrate, and the first mask film including a plurality of side surfaces defining the plurality of openings, and etching the plurality of side surfaces of the first mask film.

### CROSS-REFERENCE TO RELATED APPLICATION

The present application claims priority under 35 U.S.C. § 119 to Japanese Patent Application No. 2022-210178 filed on Dec. 27, 2022 and PCT Application No. PCT/JP2023/45598 filed on Dec. 20, 2023, the entire contents of which are incorporated herein by reference.

### BACKGROUND

### Field

An exemplary embodiment of the present disclosure relates to a method for manufacturing a semiconductor device and a substrate processing system.

### Description of Related Art

US 2022/0102346 A1 discloses a Forksheet type transistor as a structure in which an insulating backbone is disposed between two transistors.

### SUMMARY

The present disclosure provides a technique capable of adjusting a position and/or a dimension of a recess portion formed in manufacturing a semiconductor device.

In one exemplary embodiment of the present disclosure, a method for manufacturing a semiconductor device is provided. The method for manufacturing a semiconductor device, including: (a) providing a substrate including a first film stack, a dielectric film, and a first mask film, the first film stack being disposed in a first region on the substrate, the dielectric film being disposed on the substrate to cover the first film stack, and the first mask film being disposed on the dielectric film; (b) forming a plurality of openings in the first mask film, at least one of the plurality of openings being formed at a position overlapping a part of the first film stack in a plan view of the substrate, and the first mask film including a plurality of side surfaces defining the plurality of openings; (c) etching the plurality of side surfaces of the first mask film, a part of each of the plurality of side surfaces of the first mask film being selectively etched based on a positional relationship between the first film stack and the at least one of the plurality of openings to expand dimensions of the plurality of openings; (d) forming a second mask film on the plurality of side surfaces, the second mask film being formed on the plurality of side surfaces to narrow the dimension of each of the plurality of openings; and (e) forming a plurality of recess portions extending from the dielectric film to a part of the substrate using the first mask film and the second mask film as a mask.

### BRIEF DESCRIPTION OF DRAWINGS

FIG. 1 is a diagram for describing a configuration example of a substrate processing system.

FIG. 2 is a flowchart illustrating an example of a method for manufacturing a semiconductor device.

FIG. 3A is a top view illustrating an example of a substrate 100 provided in step ST1.

FIG. 3B is a view illustrating an example of a cross-sectional structure of the substrate 100 taken along line AA′ of FIG. 3A.

FIG. 4A is a top view illustrating an example of the substrate 100 in which an opening OP is formed in step ST2.

FIG. 4B is a view illustrating an example of a cross-sectional structure of the substrate 100 taken along line AA′ of FIG. 4A.

FIG. 5A is a top view illustrating an example of the substrate 100 in which the position of the opening OP is adjusted in step ST5.

FIG. 5B is a view illustrating an example of a cross-sectional structure of the substrate 100 taken along line AA′ of FIG. 5A.

FIG. 6A is a top view illustrating an example of the substrate 100 after a mask film 114 is formed in step ST5.

FIG. 6B is a view illustrating an example of a cross-sectional structure of the substrate 100 taken along line AA′ of FIG. 6A.

FIG. 7A is a top view illustrating an example of the substrate 100 after the mask film 114 is etched in step ST5.

FIG. 7B is a view illustrating an example of a cross-sectional structure of the substrate 100 taken along line AA′ of FIG. 7A.

FIG. 8A is a top view illustrating an example of the substrate 100 after a recess portion RC is formed in step ST6.

FIG. 8B is a view illustrating an example of a cross-sectional structure of the substrate 100 taken along line AA′ of FIG. 8A.

### DETAILED DESCRIPTION

Hereinafter, each embodiment according to the present disclosure will be described.

In one exemplary embodiment, a method for manufacturing a semiconductor device is provided. The method for manufacturing a semiconductor device, including: (a) providing a substrate including a first film stack, a dielectric film, and a first mask film, the first film stack being disposed in a first region on the substrate, the dielectric film being disposed on the substrate to cover the first film stack, and the first mask film being disposed on the dielectric film; (b) forming a plurality of openings in the first mask film, at least one of the plurality of openings being formed at a position overlapping a part of the first film stack in a plan view of the substrate, and the first mask film including a plurality of side surfaces defining the plurality of openings; (c) etching the plurality of side surfaces of the first mask film, a part of each of the plurality of side surfaces of the first mask film being selectively etched based on a positional relationship between the first film stack and the at least one of the plurality of openings to expand dimensions of the plurality of openings; (d) forming a second mask film on the plurality of side surfaces, the second mask film being formed on the plurality of side surfaces to narrow the dimension of each of the plurality of openings; and (e) forming a plurality of recess portions extending from the dielectric film to a part of the substrate using the first mask film and the second mask film as a mask.

In one exemplary embodiment, the method for manufacturing a semiconductor device further includes measuring the positional relationship between the first film stack and at least one of the plurality of openings between the (b) and the (c).

In one exemplary embodiment, the (c) includes etching the plurality of side surfaces by allowing a radical to be incident in an oblique direction with respect to center axes of the plurality of openings.

In one exemplary embodiment, in the (a), a second film stack is further disposed on the substrate, the second film stack is disposed in a second region on the substrate, and the second region is a region different from the first region, and in the (b), at least one of the plurality of openings is formed at a position overlapping a region between the first region and the second region in a plan view of the substrate.

In one exemplary embodiment, the method for manufacturing a semiconductor device further includes forming a third dielectric film in the plurality of recess portions.

In one exemplary embodiment, in the (e), at least one of the plurality of recess portions is formed to divide the first film stack.

In one exemplary embodiment, in the (a), the first film stack has a rectangular shape in a plan view of the substrate, and in the (c), the part of each of the plurality of side surfaces is etched based on a positional relationship between one side of the rectangular shape and at least one of the plurality of openings.

In one exemplary embodiment, in the (c), the part of each of the plurality of side surfaces is etched such that a center of the one side of the rectangular shape aligns with a center of the at least one of the plurality of openings.

In one exemplary embodiment, in the (e), the at least one of the plurality of recess portions is formed to divide the first film stack into two, and each of the two divided first film stacks has a same area in a plan view of the substrate.

In one exemplary embodiment, the (a) further includes forming a device isolation structure between the first region and the second region, the device isolation structure being configured to electrically isolate the first film stack and the second film stack from each other, in the (b), the at least one of the plurality of openings is formed at a position overlapping the device isolation structure in a plan view of the substrate, and in the (e), at least one of the plurality of recess portions is formed extending from the dielectric film to the device isolation structure.

In one exemplary embodiment, a substrate processing system that processes a substrate including a first film stack, a dielectric film, and a first mask film is provided. The substrate processing system is provided in which the first film stack is disposed in a first region on the substrate, the dielectric film is disposed on the substrate to cover the first film stack, and the first mask film is disposed on the dielectric film, the substrate processing system, including: a module configured to form a plurality of openings in the first mask film, at least one of the plurality of openings being formed at a position overlapping a part of the first film stack in a plan view of the substrate, and the first mask film including a plurality of side surfaces defining the plurality of openings; a module configured to etch the plurality of side surfaces of the first mask film, a part of each of the plurality of side surfaces of the first mask film being selectively etched based on a positional relationship between the first film stack and the at least one of the plurality of openings to expand dimensions of the plurality of openings; a module configured to form a second mask film on the plurality of side surfaces, the second mask film being formed on the plurality of side surfaces to narrow the dimension of each of the plurality of openings; and a module configured to form a plurality of recess portions extending from the dielectric film to a part of the substrate using the first mask film and the second mask film as a mask.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Substrate Processing System>

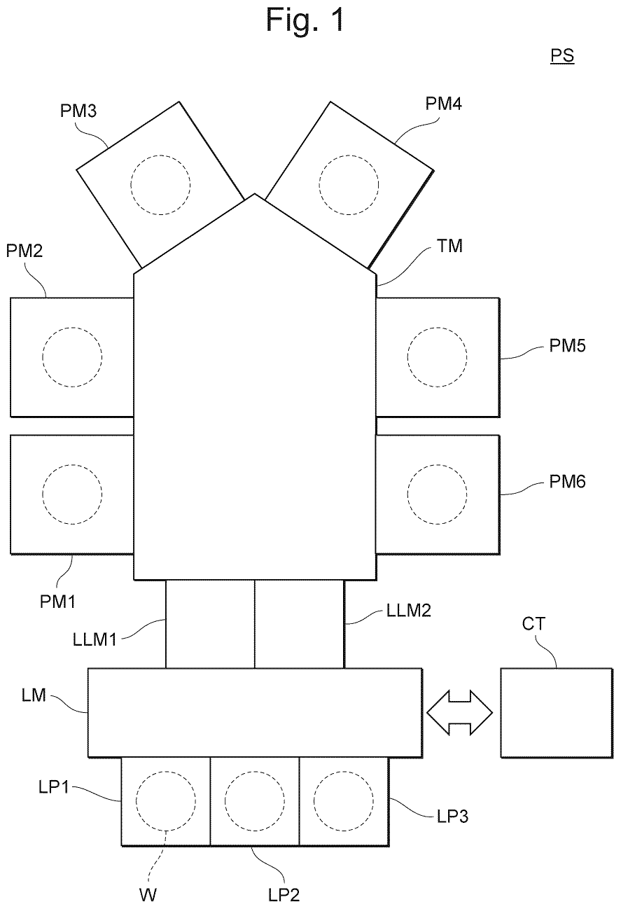

FIG. 1 is a diagram for describing a configuration example of a substrate processing system. FIG. 1 schematically illustrates the substrate processing system (hereinafter, referred to as a “substrate processing system PS”) according to one exemplary embodiment.

The substrate processing system PS includes substrate processing chambers PM1 to PM6 (hereinafter, also collectively referred to as a “substrate processing module PM”), a transport module TM, load lock modules LLM1 and LLM2 (hereinafter, also collectively referred to as a “load lock module LLM”), a loader module LM, and load ports LP1 to LP3 (hereinafter, also collectively referred to as a “load port LP”). A controller CT controls each configuration of the substrate processing system PS to execute given processing on a substrate.

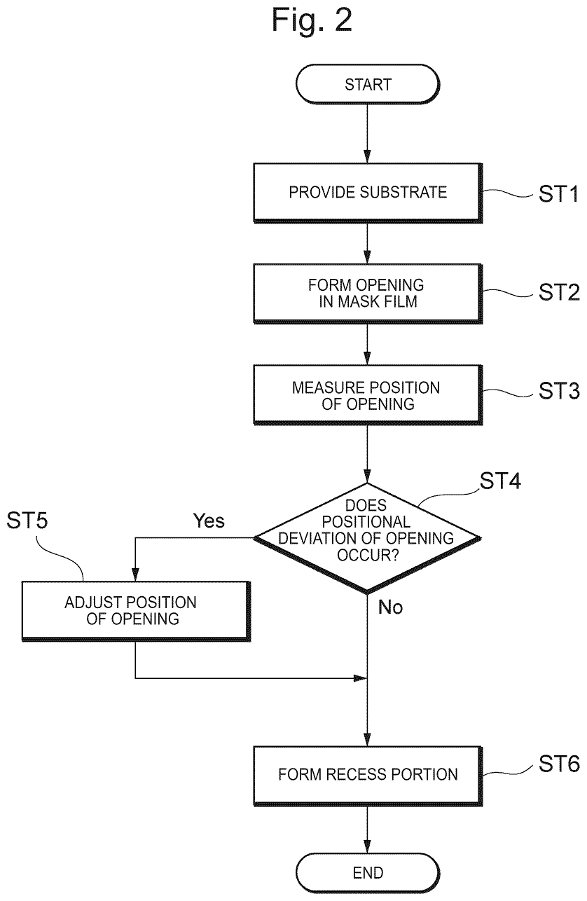

In an inside of the substrate processing module PM, etching processing, trimming processing, film formation processing, annealing processing, doping processing, lithography processing, cleaning processing, ashing processing, and the like are executed on the substrate. At least one of the substrate processing chambers PM1 to PM6 may be a plasma processing apparatus 1 illustrated in FIG. 1 or FIG. 2. In addition, at least one of the substrate processing chambers PM1 to PM6 may be a plasma processing apparatus using any plasma source such as inductively coupled plasma or microwave plasma. At least one of the substrate processing chambers PM1 to PM6 may be a measurement module, and a film thickness of a film formed on the substrate, dimensions of a pattern formed on the substrate, and the like may be measured using, for example, an optical method.

The transport module TM has a transport device that transports the substrate and transports the substrate between the substrate processing modules PM or between the substrate processing module PM and the load lock module LLM. The substrate processing module PM and the load lock module LLM are disposed adjacent to the transport module TM. The transport module TM, the substrate processing module PM, and the load lock module LLM are spatially separated or connected by a gate valve that can be opened and closed. In one embodiment, the transport device included in the transport module TM transports the substrate from the transport module TM to the substrate processing module PM.

The load lock modules LLM1 and LLM2 are provided between the transport module TM and the loader module LM. The load lock module LLM can switch a pressure therein to an atmospheric pressure or a vacuum. The “atmospheric pressure” may be an external pressure of each module included in the substrate processing system PS. In addition, the “vacuum” is a pressure lower than the atmospheric pressure, and may be, for example, a medium vacuum of 0.1 Pa to 100 Pa. The load lock module LLM transports the substrate from the loader module LM which has the atmospheric pressure to the transport module TM which has the vacuum, and also transports the substrate from the transport module TM which has the vacuum to the loader module LM which has the atmospheric pressure.

The loader module LM has the transport device that transports the substrate, and transports the substrate between the load lock module LLM and the load board LP. For example, a front opening unified pod (FOUP) capable of accommodating 25 substrates or an empty FOUP can be placed inside of the load port LP. The loader module LM takes out the substrate from the FOUP in the load port LP and transports the substrate to the load lock module LLM. In addition, the loader module LM takes out the substrate from the load lock module LLM and transports the substrate to the FOUP in the load board LP.

A controller CT controls each configuration of the substrate processing system PS to execute given processing on a substrate. The controller CT stores a recipe in which a process procedure, a process condition, a transport condition, and the like are set, and controls each configuration of the substrate processing system PS to execute given processing on the substrate according to the recipe.

### <Example of Method for Manufacturing Semiconductor Device>

FIG. 2 is a flowchart illustrating an example of a method for manufacturing a semiconductor device (hereinafter, also referred to as “the present manufacturing method”). As an example, the present manufacturing method may be a method for manufacturing a semiconductor device including a so-called nanosheet type or fork sheet type MOSFET. In addition, the present manufacturing method may be a part of manufacturing step of a semiconductor device. As an example, the steps illustrated in the flowchart of FIG. 2 may be a part of the manufacturing step of the MOSFET.

As illustrated in FIG. 2, the present manufacturing method includes a step (ST1) of providing a substrate, a step (ST2) of forming an opening in a mask film, a step (ST3) of measuring a position of the opening, a step (ST4) of determining a positional deviation of the opening, a step (ST5) of adjusting the position of the opening, and a step (ST6) of forming a recess portion.

### (Step ST1: Provision of Substrate)

In step ST1, a substrate 100 is provided to the substrate processing system PS. In one embodiment, the substrate 100 may be provided in the substrate processing system PS from the outside of the substrate processing system PS. In addition, in one embodiment, the substrate 100 may be provided from a certain module of the substrate processing system PS to another module.

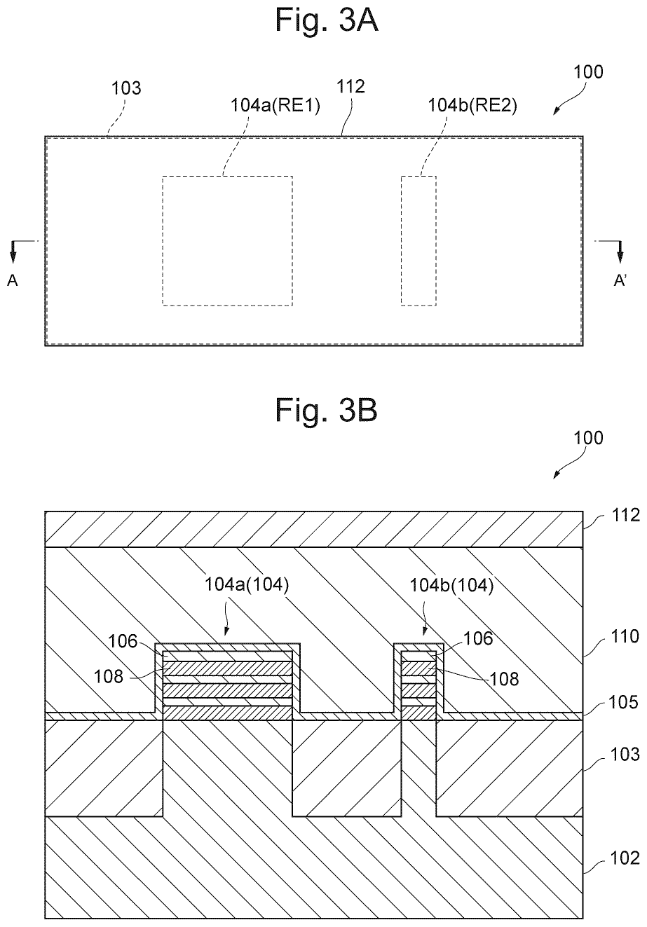

FIG. 3A is a top view illustrating an example of the substrate 100 provided in step ST1. FIG. 3B is a view illustrating an example of a cross-sectional structure of the substrate 100 taken along line AA′ of FIG. 3A. The substrate 100 may be configured to include a base material 102, a device isolation structure 103, a plurality of film stacks 104, an insulating film 105, a dielectric film 110, and a mask film 112.

The base material 102 may be a substrate made of a semiconductor material. As an example, the base material 102 is a silicon (Si) wafer. The device isolation structure 103 may be disposed on the base material 102. The device isolation structure 103 is configured to electrically separate the plurality of film stacks 104. In one embodiment, the device isolation structure 103 may be disposed around regions (RE1 and RE2) in which the plurality of film stacks 104 is disposed, as illustrated in FIG. 3A. In one embodiment, the device isolation structure 103 may be formed by forming a recess portion in the base material 102 and then filling the recess portion with a dielectric film or an insulating film. In addition, another film may be further disposed between the base material 102 and the device isolation structure 103.

The plurality of film stacks 104 is disposed on the base material 102. As illustrated in FIG. 3A, each of the plurality of film stacks 104 may have a rectangular shape in a plan view of the substrate 100. In one embodiment, the plurality of film stacks 104 may include film stacks 104a and 104b. As illustrated in FIG. 3A, the film stacks 104a and 104b may have different areas in a plan view. The film stack 104a is an example of a first film stack. The film stack 104b is an example of a second film stack.

In one embodiment, the film stack 104 may be a stack in which films 106 and 108 are alternately stacked. The films 106 and 108 may be different kinds of films. In one embodiment, the films 106 and 108 may be a semiconductor film or a dielectric film. As an example, the film 106 may be a silicon (Si) film. In addition, as an example, the film 108 may be a silicon germanium (SiGe) film. A part of the film stack 104 may be a part of a structure of a so-called Nanosheet type or Forksheet type MOSFET. In addition, a part of the film stack 104 may be a structure to be used for forming a so-called Nanosheet type or Forksheet type MOSFET.

The insulating film 105 is disposed on the device isolation structure 103 and the film stack 104. The insulating film 105 may be disposed between the device isolation structure 103 and the dielectric film 110, and the film stack 104. The insulating film 105 may be disposed to cover the device isolation structure 103 and/or the film stack 104. The insulating film 105 may be a dielectric film.

The dielectric film 110 may be formed to cover the base material 102, the device isolation structure 103, and/or the film stack 104. As an example, the dielectric film 110 may be a polysilicon film. In addition, another film may be further disposed between the dielectric film 110 and the base material 102, the device isolation structure 103, and/or the film stack 104.

The mask film 112 is formed on the dielectric film 110. In one embodiment, the mask film 112 may be formed to cover the dielectric film 110. In one embodiment, the mask film 112 may be a photoresist film. The photoresist film may be a photoresist film containing a metal. The mask film 112 is an example of a first mask film.

At least a part of the configuration included in the substrate 100 illustrated in FIGS. 3A and 3B may be formed in the substrate processing system PS. In one embodiment, a plurality of configurations included in the substrate 100 illustrated in FIGS. 3A and 3B may be continuously formed in the substrate processing system PS.

### (Step ST2: Formation of Opening)

In step ST2, a plurality of openings OP is formed in the mask film 112. In one embodiment, the opening OP may be formed in the mask film 112 by photolithography. In addition, the opening OP may be formed in the mask film 112 by etching.

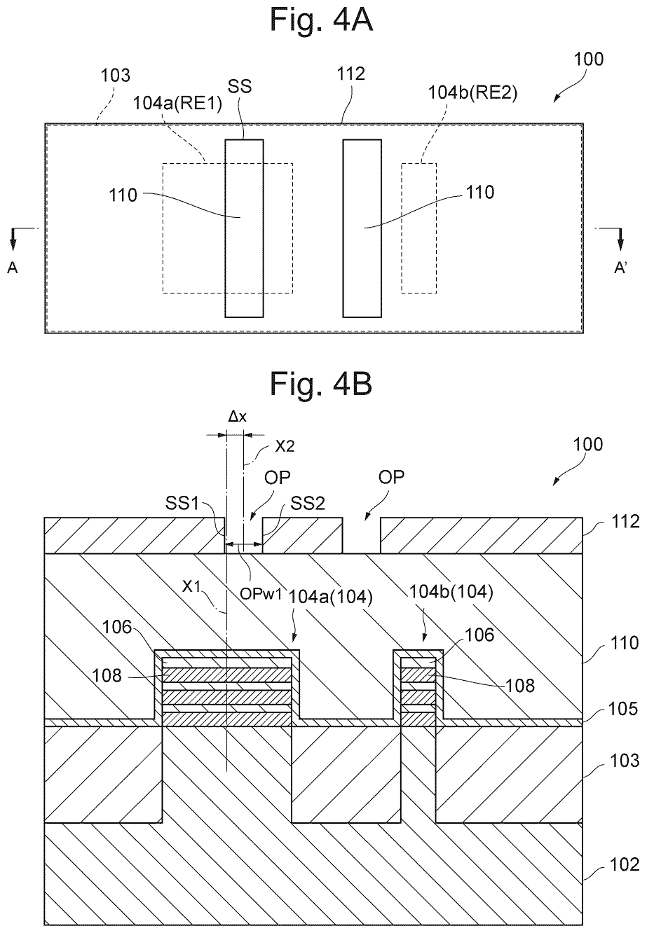

FIG. 4A is a top view illustrating an example of the substrate 100 in which the opening OP is formed in step ST2. FIG. 4B is a view illustrating an example of a cross-sectional structure of the substrate 100 taken along line AA′ of FIG. 4A.

As illustrated in FIGS. 4A and 4B, the opening OP may be a space defined by a side surface SS of the mask film 112 on the dielectric film 110. In addition, the dielectric film 110 may be exposed on a bottom surface of the opening OP. In a plan view of the substrate 100, the opening OP may have a rectangular shape. The side surface SS may include a portion SS1 and a portion SS2 facing the portion SS1. In a case where the opening OP has the rectangular shape in a plan view of the substrate 100, the portions SS1 and SS2 may be two facing sides of the rectangular shape defining the opening OP in the plan view of the substrate 100. In a case where the rectangular shape has a longitudinal direction and a lateral direction, the portions SS1 and SS2 may be two sides in the longitudinal direction. In addition, in a case where the opening OP has an elliptical shape in a plan view of the substrate 100, the portions SS1 and SS2 may be two portions facing each other in the elliptical shape. As an example, the portions SS1 and SS2 may be two portions facing each other with a long axis interposed therebetween in the elliptical shape. In FIG. 4B, a dimension (opening width) of the opening OP is OPw1. In one example, the dimension of the opening OP may be a distance between the portion SS1 and the portion SS2.

### (Step ST3: Measurement of Position of Opening)

In step ST3, the position of the opening OP is measured. In one embodiment, the position of the opening OP may be measured by an optical critical dimension (CD) measurement. In one embodiment, the position of the opening OP to be measured may be the position of the opening OP with respect to the film stack 104. As an example, a center position of the opening OP may be a center position of the film stack 104. The center position of the film stack 104 may be a center position of the film stack 104 in the lateral direction of the opening OP in a plan view of the substrate 100. In addition, the center position of the opening OP may be a center between the portion SS1 and the portion SS2.

### (Step ST4: Determination of Positional Deviation of Opening)

In step ST4, the positional deviation of the opening OP is determined. In one embodiment, first, based on the position of the opening OP measured in step ST3, a positional deviation amount of the opening OP with respect to the film stack 104 is calculated. As an example, as illustrated in FIG. 4B, in a case where the center position of the film stack 104 is X1 and the center position of the opening OP is X2, a deviation amount Δx of the opening OP with respect to the film stack 104 may be Δx=|X1−X2|. Then, in a case where Δx is larger than a predetermined value, it is determined that the positional deviation of the opening OP occurs (ST4: Yes), and the position of the opening OP is adjusted in step ST5. On the other hand, in a case where Δx is smaller than the predetermined value, it is determined that there is no positional deviation of the opening OP (ST4: No), and the recess portion RC is formed in Step ST6.

### (Step ST5: Adjustment of Position of Opening)

In step ST5, the position of the opening OP is adjusted. In one embodiment, the position of the opening OP may be a center position X2 between the portion SS1 and the portion SS2 of the side surface SS of the mask film 112. Then, the side surface SS of the mask film 112 defining the opening OP is etched such that the center position X2 of the opening OP aligns with the center position X1 of the film stack 104. For example, in the example illustrated in FIG. 4B, since the center position X2 of the opening OP is deviated to the right from the center position X1 of the film stack 104, the side surface SS is etched such that the portion SS1 is more etched than the portion SS2 in the side surfaces SS. In one embodiment, only the portion SS1 of the side surface SS may be etched. In an example, a radical serving as an etchant is obliquely incident with respect to a depth direction of the opening OP (direction from the top to the bottom in FIG. 4B) using a gas cluster ion beam (GCIB). As a result, the portion SS1 of the side surface SS can be selectively etched.

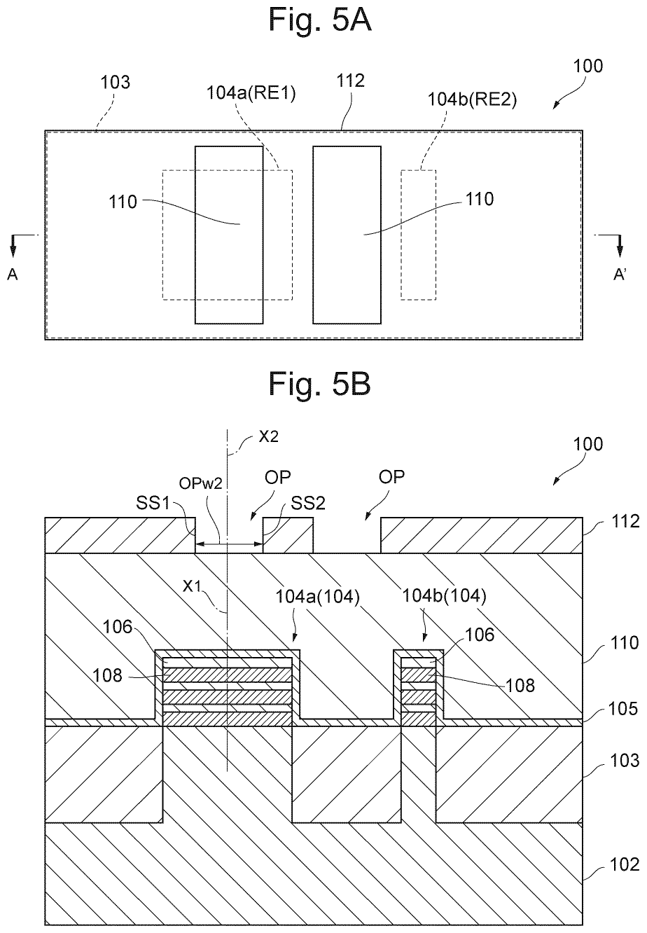

FIG. 5A is a top view illustrating an example of the substrate 100 in which the position of the opening OP is adjusted in step ST5. FIG. 5B is a view illustrating an example of a cross-sectional structure of the substrate 100 taken along line AA′ of FIG. 5A. For example, as illustrated in FIG. 4B, in a case where the center position X2 of the opening OP is deviated to the right from the center position X1 of the film stack 104, the dimension of the opening OP may be expanded to a left direction in FIG. 4B by selectively etching the portion SS1 of the side surface SS. As a result, as illustrated in FIG. 5B, the center position X2 of the opening OP may be made to align with the center position X1 of the film stack 104. In addition, in FIG. 5B, the dimension of the opening OP is OPw2. The dimension OPw2 may be larger than a dimension OPw1 (see FIG. 4B).

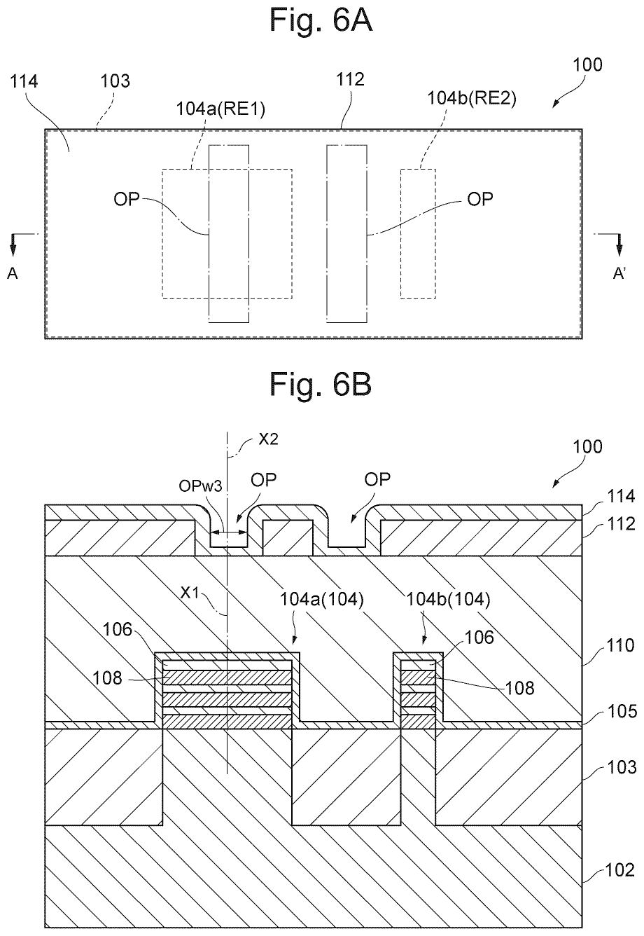

FIG. 6A is a top view illustrating an example of the substrate 100 after the mask film 114 is formed in step ST5. FIG. 6B is a view illustrating an example of a cross-sectional structure of the substrate 100 taken along line AA′ of FIG. 6A. The dimension of the opening OP is expanded, and the center position X2 of the opening OP is made to align with the center position X1 of the film stack 104. Then, as illustrated in FIGS. 6A and 6B, the mask film 114 is formed on the mask film 112. In one embodiment, the mask film 114 may be formed on the mask film 112 with a thickness such that a dimension OPw3 of the opening OP is a predetermined dimension. As an example, the predetermined dimension may be the dimension OPw1 of the opening OP formed in the mask film 112 in step ST2. Accordingly, the dimension (opening width) of the opening OP can be adjusted to any dimension. The mask film 114 is an example of a second mask film.

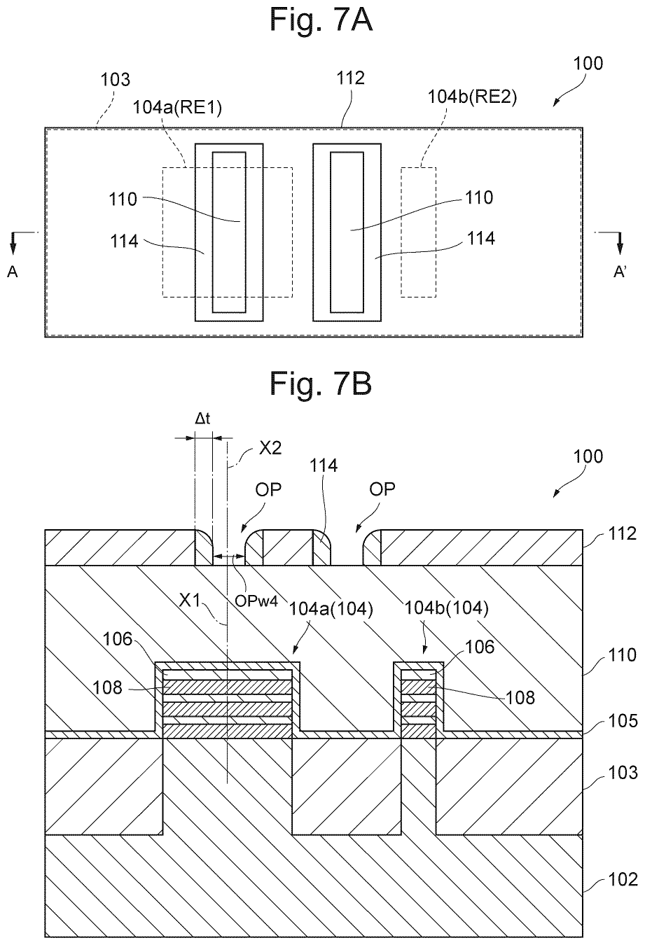

FIG. 7A is a top view illustrating an example of the substrate 100 after the mask film 114 is etched in step ST5. FIG. 7B is a view illustrating an example of a cross-sectional structure of the substrate 100 taken along line AA′ of FIG. 7A. In one embodiment, as illustrated in FIGS. 7A and 7B, a part of the mask film 114 is etched. As a result, the dielectric film 110 may be exposed at the bottom portion of the opening OP. In FIG. 7B, the dimension of the opening OP is OPw4. The dimension OPw4 may be the same dimension as the dimension OPw1 (see FIG. 4B) and/or the dimension OPw3 (see FIG. 6). In addition, the dimension OPw4 may be larger than the dimension OPw3 (see FIG. 6).

### (Step ST6: Formation of Recess Portion)

In step ST6, the recess portion RC is formed. In one embodiment, the dielectric film 110 is etched using the mask film 112 and the mask film 114 as masks, whereby the recess portion RC is formed in the dielectric film 110.

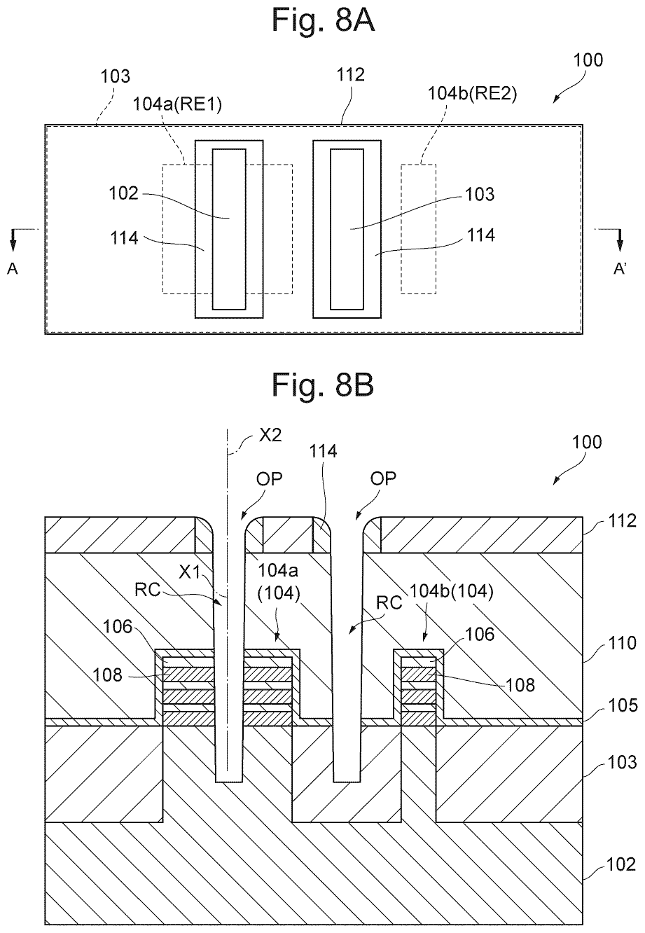

FIG. 8A is a top view illustrating an example of the substrate 100 after the recess portion RC is formed in step ST6. FIG. 8B is a view illustrating an example of a cross-sectional structure of the substrate 100 taken along line AA′ of FIG. 8A. As illustrated in FIGS. 8A and 8B, the recess portion RC may be formed extending from the dielectric film 110 to the film stack 104a and the base material 102, in at least one of the plurality of openings OP. In addition, in the opening OP formed at a position overlapping the device isolation structure 103 in a plan view of the substrate 100 among the plurality of openings OPs, the recess portion RC may be formed extending from the dielectric film 110 to the device isolation structure 103.

In addition, after the recess portion RC is formed, the recess portion RC may be filled with a dielectric film or an insulating film. As a result, each of the two divided film stacks 104a may be electrically separated from each other. In one embodiment, a p-type MOSFET may be formed in one of the two divided film stacks 104a, and an n-type MOSFET may be formed in the other.

According to the above-described exemplary embodiment, since the position of the opening OP can be corrected, the recess portion RC can be formed at an appropriate position of the substrate 100. For example, even in a case where there is a positional deviation in the opening OP formed in the mask film 112, the recess portion RC can be formed at the center of the film stack 104a. As a result, the film stack 104a can be appropriately divided.

According to one exemplary embodiment of the present disclosure, it is possible to provide a technique that can adjust a position and/or a dimension of a recess portion formed in the manufacturing of a semiconductor device.

The present disclosure may include, for example, the following configurations.

### (Addendum 1)

A method for manufacturing a semiconductor device, including:
(a) providing a substrate including a first film stack, a dielectric film, and a first mask film, the first film stack being disposed in a first region on the substrate, the dielectric film being disposed on the substrate to cover the first film stack, and the first mask film being disposed on the dielectric film;
(b) forming a plurality of openings in the first mask film, at least one of the plurality of openings being formed at a position overlapping a part of the first film stack in a plan view of the substrate, and the first mask film including a plurality of side surfaces defining the plurality of openings;
(c) etching the plurality of side surfaces of the first mask film, a part of each of the plurality of side surfaces of the first mask film being selectively etched based on a positional relationship between the first film stack and the at least one of the plurality of openings to expand dimensions of the plurality of openings;
(d) forming a second mask film on the plurality of side surfaces, the second mask film being formed on the plurality of side surfaces to narrow the dimension of each of the plurality of openings; and
(e) forming a plurality of recess portions extending from the dielectric film to a part of the substrate using the first mask film and the second mask film as a mask.

### (Addendum 2)

The method for manufacturing a semiconductor device according to Addendum 1, further including:
measuring the positional relationship between the first film stack and the at least one of the plurality of openings between the (b) and the (c).

### (Addendum 3)

The method for manufacturing a semiconductor device according to Addendum 1 or 2, in which the (c) includes etching the plurality of side surfaces by allowing a radical to be incident in an oblique direction with respect to center axes of the plurality of openings.

### (Addendum 4)

The method for manufacturing a semiconductor device according to any one of Addenda 1 to 3, in which,
in the (a), a second film stack is further disposed on the substrate, the second film stack is disposed in a second region on the substrate, and the second region is a region different from the first region, and
in the (b), at least one of the plurality of openings is formed at a position overlapping a region between the first region and the second region in a plan view of the substrate.

### (Addendum 5)

The method for manufacturing a semiconductor device according to any one of Addenda 1 to 4, further including:
forming a third dielectric film in the plurality of recess portions.

### (Addendum 6)

The method for manufacturing a semiconductor device according to any one of Addenda 1 to 5, in which, in the (e), at least one of the plurality of recess portions is formed to divide the first film stack.

### (Addendum 7)

The method for manufacturing a semiconductor device according to Addendum 6, in which,
in the (a), the first film stack has a rectangular shape in a plan view of the substrate, and
in the (c), the part of each of the plurality of side surfaces is etched based on a positional relationship between one side of the rectangular shape and at least one of the plurality of openings.

### (Addendum 8)

The method for manufacturing a semiconductor device according to Addendum 7, in which, in the (c), the part of each of the plurality of side surfaces is etched such that a center of the one side of the rectangular shape aligns with a center of the at least one of the plurality of openings.

### (Addendum 9)

The method for manufacturing a semiconductor device according to Addendum 8, in which, in the (e), the at least one of the plurality of recess portions is formed to divide the first film stack into two, and each of the two divided first film stacks has a same area in a plan view of the substrate.

### (Addendum 10)

The method for manufacturing a semiconductor device according to Addendum 4, in which
the (a) further includes forming a device isolation structure between the first region and the second region, the device isolation structure being configured to electrically isolate the first film stack and the second film stack from each other,
in the (b), the at least one of the plurality of openings is formed at a position overlapping the device isolation structure in a plan view of the substrate, and
in the (e), at least one of the plurality of recess portions is formed extending from the dielectric film to the device isolation structure.

### (Addendum 11)

A substrate processing system that processes a substrate including a first film stack, a dielectric film, and a first mask film, the first film stack being disposed in a first region on the substrate, the dielectric film being disposed on the substrate to cover the first film stack, and the first mask film being disposed on the dielectric film, the substrate processing system, including:
a module configured to form a plurality of openings in the first mask film, at least one of the plurality of openings being formed at a position overlapping a part of the first film stack in a plan view of the substrate, and the first mask film including a plurality of side surfaces defining the plurality of openings;
a module configured to etch the plurality of side surfaces of the first mask film, a part of each of the plurality of side surfaces of the first mask film being selectively etched based on a positional relationship between the first film stack and the at least one of the plurality of openings to expand dimensions of the plurality of openings;
a module configured to form a second mask film on the plurality of side surfaces, the second mask film being formed on the plurality of side surfaces to narrow the dimension of each of the plurality of openings; and
a module configured to form a plurality of recess portions extending from the dielectric film to a part of the substrate using the first mask film and the second mask film as a mask.

The above-described exemplary embodiments may be modified in various ways without departing from the scope and the spirit of the present disclosure. For example, some components in one embodiment can be added to another embodiment within the range of the ordinary creativity of those skilled in the art.

In addition, some configuration elements in one embodiment may be replaced with corresponding configuration elements in another embodiment.

What is claimed is:

1. A method for manufacturing a semiconductor device, comprising:
(a) providing a substrate including a first film stack, a dielectric film, and a first mask film, the first film stack being disposed in a first region on the substrate, the dielectric film being disposed on the substrate to cover the first film stack, and the first mask film being disposed on the dielectric film;
(b) forming a plurality of openings in the first mask film, at least one of the plurality of openings being formed at a position overlapping a part of the first film stack in a plan view of the substrate, and the first mask film including a plurality of side surfaces defining the plurality of openings;
(c) etching the plurality of side surfaces of the first mask film, a part of each of the plurality of side surfaces of the first mask film being selectively etched based on a positional relationship between the first film stack and the at least one of the plurality of openings to expand dimensions of the plurality of openings;
(d) forming a second mask film on the plurality of side surfaces, the second mask film being formed on the plurality of side surfaces to narrow the dimension of each of the plurality of openings; and
(e) forming a plurality of recess portions extending from the dielectric film to a part of the substrate using the first mask film and the second mask film as a mask.

2. The method for manufacturing a semiconductor device according to claim 1, further comprising:
measuring the positional relationship between the first film stack and the at least one of the plurality of openings between the (b) and the (c).

3. The method for manufacturing a semiconductor device according to claim 1, wherein the (c) includes etching the plurality of side surfaces by allowing a radical to be incident in an oblique direction with respect to center axes of the plurality of openings.

4. The method for manufacturing a semiconductor device according to claim 1, wherein,
in the (a), a second film stack is further disposed on the substrate, the second film stack is disposed in a second region on the substrate, and the second region is a region different from the first region, and
in the (b), at least one of the plurality of openings is formed at a position overlapping a region between the first region and the second region in a plan view of the substrate.

5. The method for manufacturing a semiconductor device according to claim 1, further comprising:
forming a third dielectric film in the plurality of recess portions.

6. The method for manufacturing a semiconductor device according to claim 1, wherein, in the (e), at least one of the plurality of recess portions is formed to divide the first film stack.

7. The method for manufacturing a semiconductor device according to claim 6, wherein,
in the (a), the first film stack has a rectangular shape in a plan view of the substrate, and
in the (c), the part of each of the plurality of side surfaces is etched based on a positional relationship between one side of the rectangular shape and at least one of the plurality of openings.

8. The method for manufacturing a semiconductor device according to claim 7, wherein, in the (c), the part of each of the plurality of side surfaces is etched such that a center of the one side of the rectangular shape aligns with a center of the at least one of the plurality of openings.

9. The method for manufacturing a semiconductor device according to claim 8, wherein, in the (e), the at least one of the plurality of recess portions is formed to divide the first film stack into two, and each of the two divided first film stacks has a same area in a plan view of the substrate.

10. The method for manufacturing a semiconductor device according to claim 4, wherein
the (a) further includes forming a device isolation structure between the first region and the second region, the device isolation structure being configured to electrically isolate the first film stack and the second film stack from each other,
in the (b), the at least one of the plurality of openings is formed at a position overlapping the device isolation structure in a plan view of the substrate, and
in the (e), at least one of the plurality of recess portions is formed extending from the dielectric film to the device isolation structure.

11. A substrate processing system that processes a substrate including a first film stack, a dielectric film, and a first mask film, the first film stack being disposed in a first region on the substrate, the dielectric film being disposed on the substrate to cover the first film stack, and the first mask film being disposed on the dielectric film, the substrate processing system, comprising:
a module configured to form a plurality of openings in the first mask film, at least one of the plurality of openings being formed at a position overlapping a part of the first film stack in a plan view of the substrate, and the first mask film including a plurality of side surfaces defining the plurality of openings;
a module configured to etch the plurality of side surfaces of the first mask film, a part of each of the plurality of side surfaces of the first mask film being selectively etched based on a positional relationship between the first film stack and the at least one of the plurality of openings to expand dimensions of the plurality of openings;
a module configured to form a second mask film on the plurality of side surfaces, the second mask film being formed on the plurality of side surfaces to narrow the dimension of each of the plurality of openings; and
a module configured to form a plurality of recess portions extending from the dielectric film to a part of the substrate using the first mask film and the second mask film as a mask.
